(19) United States
(12) Patent Application Publication
(10) Pub. No.: US 2025/0112594 A1
(43) Pub. Date: Apr. 3, 2025

(54) SPREAD SPECTRUM CLOCK GENERATION CIRCUIT

(71) Applicant: LAPIS Technology Co., Ltd., Yokohama (JP)

(72) Inventor: Suguru KAWASOE, Yokohama (JP)

(73) Assignee: LAPIS Technology Co., Ltd., Yokohama (JP)

(21) Appl. No.: 18/896,819

(22) Filed: Sep. 25, 2024

(30) Foreign Application Priority Data
Sep. 29, 2023 (JP) 2023-170663

(51) Int. Cl. H03B 5/20

(52) U.S. Cl. CPC H03B 5/20

(57) ABSTRACT

A flash memory is a memory element that stores a trimming code for adjusting a resistance value of a trimming resistor so that an oscillation frequency of an output clock signal generated by a CR oscillator circuit becomes a preset frequency. The CR oscillator circuit generates the output clock signal having a frequency based on a time constant determined by a resistance value of the trimming resistor being a resistive element, and a capacitance value of a capacitive element. An up-down counter is a counter circuit that, in synchronization with the output clock signal generated by the CR oscillator circuit, increases or decreases the trimming code stored in the flash memory, and outputs the trimming code as a trimming code for adjusting the resistance value of the trimming resistor.

### CROSS-REFERENCE TO RELATED APPLICATIONS

This application claims the priority benefit of Japan Application No. 2023-170663, filed on Sep. 29, 2023. The entirety of the above-described patent application is hereby incorporated by reference herein and made a part of the present specification.

### BACKGROUND

### Technical Field

The disclosure relates to a spread spectrum clock generation circuit.

### Related Art

In a microcontroller unit (MCU), in addition to improved noise immunity (electromagnetic susceptibility (EMS)), a reduced amount of noise generated by the MCU itself and suppressed electromagnetic interference (EMI) are also required. To suppress the generation of EMI, a technology called spread spectrum is used to intentionally change a frequency of a clock signal that operates the MCU, thereby suppressing a peak amount of generated noise and preventing malfunction of peripheral devices.

As a spread spectrum clock generation circuit that changes a frequency of a clock signal generated using such a spread spectrum technology, a clock generation circuit using a phase locked loop (PLL) circuit has been widely utilized (for example, see Japanese Patent Laid-Open No. 2007-243911).

In a PLL circuit, a feedback loop is formed that compares a reference clock with a feedback clock in terms of phase and frequency. In the PLL circuit, when a frequency division number of a frequency divider circuit that divides the feedback clock changes, a frequency of an output clock also changes. Hence, the frequency division number is changed to thereby control and change the frequency of the clock. Generally, the PLL circuit is mounted with a voltage-controlled oscillator (VCO) whose frequency changes according to a control voltage. By performing dithering that adds a triangular wave to the control voltage input to this voltage-controlled oscillator, an output frequency is periodically changed.

Here, the MCU often includes multiple clock generation circuits, and the clock generation circuit in use may be switched as needed. In such cases, if a clock generation circuit other than the clock generation circuit using the PLL circuit as described above is selected, the measure taken against EMI by spread spectrum may become no longer feasible. For example, as a clock generation circuit widely used in the MCU, there are cases of using a capacitor-resistor (CR) oscillator circuit that generates a clock signal having a frequency based on a time constant determined by a resistance value (R) of a resistive element and a capacitance value (C) of a capacitive element.

However, the spread spectrum technology that may be applied to the PLL circuit is not applicable to the CR oscillator circuit. It is desirable to realize a spread spectrum technology in which, even in a clock generation circuit configured to generate a clock signal using a CR oscillator circuit, a frequency of the generated clock signal can be changed.

The disclosure provides a spread spectrum clock generation circuit capable of realizing a spread spectrum technology in which, even if a clock signal is generated using a CR oscillator circuit, a frequency of the generated clock signal can be changed.

### SUMMARY

A spread spectrum clock generation circuit according to the disclosure includes: a CR oscillator circuit, generating a clock signal having a frequency based on a time constant determined by a resistance value of a resistive element and a capacitance value of a capacitive element; a memory element, storing a trimming code for adjusting the resistance value of the resistive element or the capacitance value of the capacitive element so that the frequency of the clock signal generated by the CR oscillator circuit becomes a preset frequency; and a counter circuit, in synchronization with the clock signal generated by the CR oscillator circuit, increasing or decreasing the trimming code stored in the memory element and outputting the trimming code as the trimming code for adjusting the resistance value of the resistive element or the capacitance value of the capacitive element.

### BRIEF DESCRIPTION OF THE DRAWINGS

FIG. 1 illustrates a circuit configuration of a clock generation circuit using a PLL circuit, which is a comparative example.

FIG. 2 illustrates a circuit configuration of an example of a spread spectrum clock generation circuit using a PLL circuit.

FIG. 3 illustrates, as a comparative example, a clock generation circuit using a CR oscillator circuit.

FIG. 4 illustrates a relationship between trimming code and oscillation frequency in a CR oscillator circuit 30.

FIG. 5 illustrates a circuit configuration of a spread spectrum clock generation circuit according to one embodiment of the disclosure.

FIG. 6 illustrates an operation waveform in the spread spectrum clock generation circuit of the present embodiment illustrated in FIG. 5.

### DESCRIPTION OF THE EMBODIMENTS

A spread spectrum clock generation circuit according to the disclosure includes: a CR oscillator circuit, generating a clock signal having a frequency based on a time constant determined by a resistance value of a resistive element and a capacitance value of a capacitive element; a memory element, storing a trimming code for adjusting the resistance value of the resistive element or the capacitance value of the capacitive element so that the frequency of the clock signal generated by the CR oscillator circuit becomes a preset frequency; and a counter circuit, in synchronization with the clock signal generated by the CR oscillator circuit, increasing or decreasing the trimming code stored in the memory element and outputting the trimming code as the trimming code for adjusting the resistance value of the resistive element or the capacitance value of the capacitive element.

In the spread spectrum clock generation circuit according to the disclosure, the counter circuit may increase or decrease and change the trimming code stored in the memory element so that the trimming code to be output falls within a preset range from the trimming code stored in the memory element.

In the spread spectrum clock generation circuit according to the disclosure, the resistive element may be a ladder-type trimming resistor whose resistance value changes based on an input trimming code. The memory element may store the trimming code for adjusting the resistance value of the resistive element so that the frequency of the clock signal generated by the CR oscillator circuit becomes a preset frequency. The counter circuit may, in synchronization with the clock signal generated by the CR oscillator circuit, increase or decrease the trimming code stored in the memory element and output the trimming code as the trimming code for adjusting the resistance value of the resistive element.

Furthermore, in the spread spectrum clock generation circuit according to the disclosure, the CR oscillator circuit is a feedback-type oscillator circuit that is composed of an amplifier circuit and a feedback circuit and oscillates and generates a clock signal in response to satisfying an oscillation condition, or is a relaxation-type oscillator circuit that generates a clock signal by controlling an on/off timing of a switching element.

According to the disclosure, a spread spectrum clock generation circuit can be provided that is capable of realizing a spread spectrum technology in which, even if a clock signal is generated using a CR oscillator circuit, a frequency of the generated clock signal can be changed.

Next, an embodiment of the disclosure will be described in detail with reference to the drawings.

First, before describing a spread spectrum clock generation circuit of the present embodiment, a circuit configuration of a general clock generation circuit using a PLL circuit will be described as a comparative example.

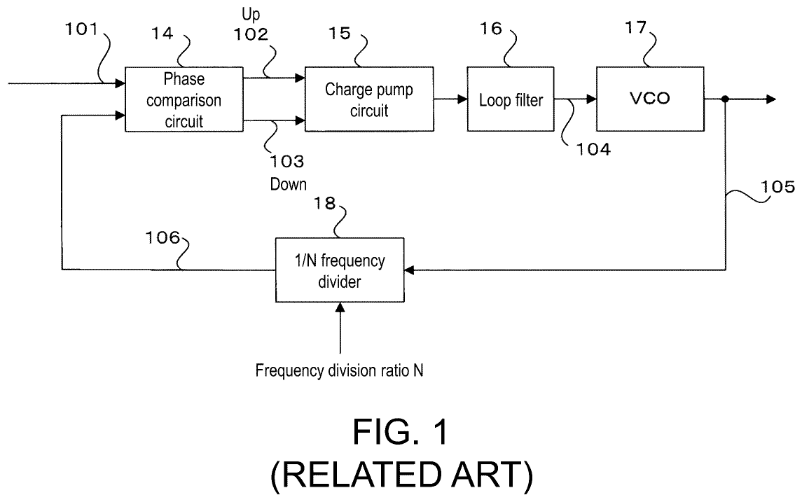

FIG. 1 illustrates the circuit configuration of the clock generation circuit using the PLL circuit, which is a comparative example.

As illustrated in FIG. 1, this clock generation circuit as a comparative example includes a phase comparison circuit 14, a charge pump circuit 15, a loop filter (LPF) 16, a voltage-controlled oscillator (VCO) 17, and a 1/N frequency divider 18.

The phase comparison circuit 14 detects a phase difference between a feedback clock signal 106 and a reference clock signal 101. In the case where the phase of the reference clock signal 101 is ahead of the phase of the feedback clock signal 106, the phase comparison circuit 14 outputs an up pulse signal 102 to the charge pump circuit 15. In the case where the phase of the reference clock signal 101 is behind the phase of the feedback clock signal 106, the phase comparison circuit 14 outputs a down pulse signal 103 to the charge pump circuit 15.

The charge pump circuit 15 increases or decreases an output voltage based on the up pulse signal 102 or the down pulse signal 103. Specifically, the charge pump circuit 15 increases the output voltage upon receiving the up pulse signal 102, and decreases the output voltage upon receiving the down pulse signal 103.

The loop filter (LPF) 16 is a filter circuit that smooths the output voltage from the charge pump circuit 15 and outputs it as a control voltage 104 to the VCO 17.

Due to the circuit configuration described above, when the up pulse signal 102 is output from the phase comparison circuit 14, the control voltage 104 increases; when the down pulse signal 103 is output from the phase comparison circuit 14, the control voltage 104 decreases.

The voltage-controlled oscillator (VCO) 17 generates an output clock signal 105 having an oscillation frequency corresponding to the control voltage 104 input from the loop filter 16.

The 1/N frequency divider 18 is a frequency divider circuit that divides a frequency of the output clock signal 105 generated by the VCO 17 by a set frequency division ratio N, and outputs a resultant as the feedback clock signal 106.

As a result of the above operation, in the clock generation circuit using the PLL circuit illustrated in FIG. 1, the frequency of the output clock signal 105 is controlled by setting the frequency division ratio N with respect to the 1/N frequency divider 18. In other words, by changing the frequency division ratio N, the frequency of the output clock signal 105 can be controlled. For example, in the case where the frequency division ratio N set with respect to the 1/N frequency divider 18 is 100, the frequency of the output clock signal 105 becomes 100 times the frequency of the reference clock signal 101.

As described above, the VCO 17 is configured to generate and output the output clock signal 105 having a frequency corresponding to the input control voltage 104. Hence, it is possible to change the frequency of the output clock signal 105 by changing the control voltage 104.

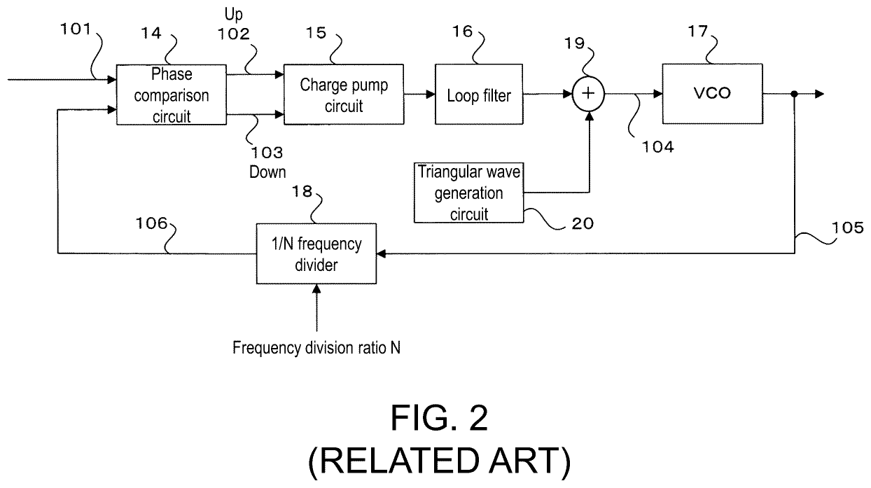

By utilizing such a feature of the PLL circuit, a spread spectrum clock generation circuit can be realized. FIG. 2 illustrates a circuit configuration of an example of a spread spectrum clock generation circuit using a PLL circuit.

The spread spectrum clock generation circuit illustrated in FIG. 2 has a configuration in which an adder 19 and a triangular wave generation circuit 20 are added to the circuit configuration illustrated in FIG. 1.

The triangular wave generation circuit 20 generates and outputs a triangular wave. The adder 19 adds the triangular wave generated by the triangular wave generation circuit 20 to a voltage smoothed by the loop filter 16, and outputs a resultant as the control voltage 104 to the VCO 17.

In the spread spectrum clock generation circuit illustrated in FIG. 2, the control voltage 104 input to the VCO 17 is not constant but fluctuates due to the added triangular wave. Hence, the frequency of the output clock signal 105 generated by the VCO 17 also fluctuates, causing a spectrum of a noise component from the output clock signal 105 to spread.

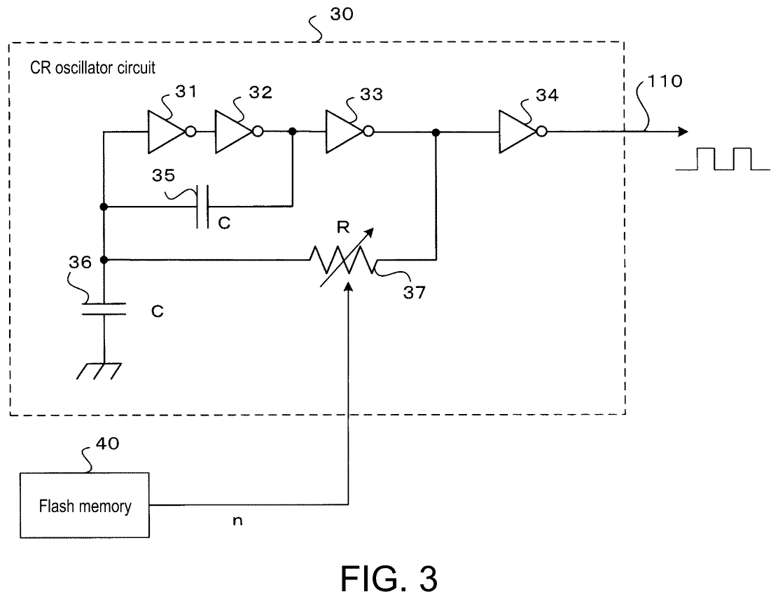

Next, FIG. 3 illustrates, as a comparative example, a clock generation circuit using a CR oscillator circuit instead of the clock generation circuit using the PLL circuit as illustrated in FIG. 1 and FIG. 2.

The clock generation circuit illustrated in FIG. 3 is composed of a CR oscillator circuit 30 and a flash memory 40. The CR oscillator circuit 30 is composed of inverter circuits 31 to 34 connected in series, capacitive elements 35 and 36, and a trimming resistor 37.

The CR oscillator circuit 30 illustrated in FIG. 3 generates an output clock signal 110 having a frequency based on a time constant determined by a resistance value R of the trimming resistor 37 being a resistive element, and a capacitance value C of the capacitive elements 35 and 36. Specifically, the CR oscillator circuit 30 generates the output clock signal 110 having an oscillation frequency proportional to the reciprocal of a time constant CR determined by the resistance value R of the trimming resistor 37 and the capacitance value C of the capacitive elements 35 and 36.

However, as capacitive elements or resistive elements generated on a semiconductor wafer vary from chip to chip, the generated output clock signal 110 has a varying oscillation frequency. Accordingly, in the CR oscillator circuit 30 illustrated in FIG. 3, by using, as the resistive element, the trimming resistor 37 whose resistance value can be changed, the chip-to-chip variation in oscillation frequency is suppressed so that the output clock signal 110 can be obtained having a constant frequency.

Here, the trimming resistor 37 is a ladder-type trimming resistor whose resistance value changes based on an input trimming code.

The flash memory 40 is a memory element that stores a trimming code for adjusting the resistance value of the trimming resistor 37 so that the oscillation frequency of the output clock signal 110 generated by the CR oscillator circuit 30 becomes a preset frequency.

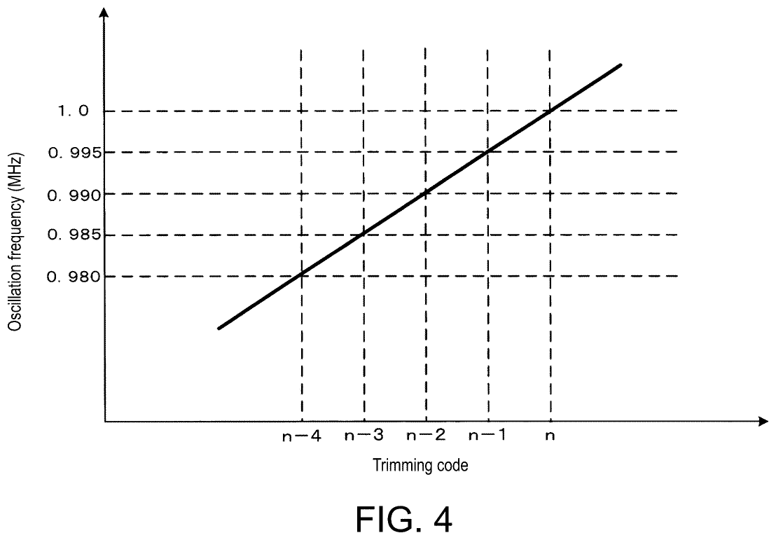

Here, a description is given of adjusting the frequency of the output clock signal 110 to 1 MHz. Also described is that a relationship between trimming code and oscillation frequency in the CR oscillator circuit 30 follows a relationship as illustrated in FIG. 4.

As can be understood from FIG. 4, if the trimming code is n, the oscillation frequency of the output clock signal 110 of the CR oscillator circuit 30 is configured to become 1 MHz; if the trimming code is n-1, the oscillation frequency is configured to become 0.995 MHz. In other words, when the trimming code changes by 1, the oscillation frequency changes by approximately 0.5%.

In the clock generation circuit illustrated in FIG. 3, to set the oscillation frequency of the output clock signal 110 to 1 MHz, it is assumed that a value n is stored as the trimming code in the flash memory 40.

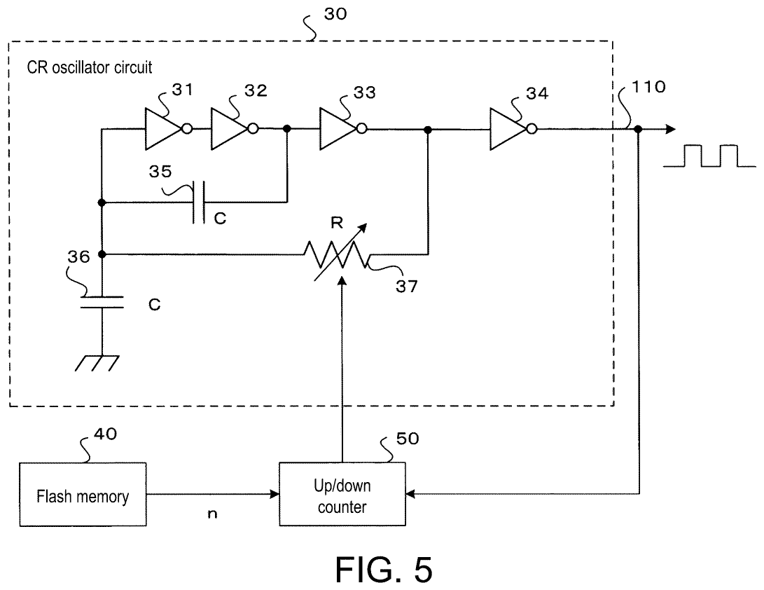

Next, FIG. 5 illustrates a circuit configuration of a spread spectrum clock generation circuit according to one embodiment of the disclosure, in which a spread spectrum technology is applied to the clock generation circuit using the CR oscillator circuit illustrated in FIG. 3.

The spread spectrum clock generation circuit according to one embodiment of the disclosure illustrated in FIG. 5 has a configuration in which an up-down counter 50 is added to the clock generation circuit illustrated in FIG. 3 as a comparative example.

The up-down counter 50 is a counter circuit that, in synchronization with the output clock signal 110 generated by the CR oscillator circuit 30, increases or decreases a trimming code stored in the flash memory 40, and outputs the trimming code as the trimming code for adjusting the resistance value of the trimming resistor 37. Specifically, the up-down counter 50 changes and outputs the trimming code in synchronization with rising of the output clock signal 110.

The up-down counter 50 increases or decreases and changes the trimming code n stored in the flash memory 40, so that the trimming code output to the trimming resistor 37 falls within a preset range from the trimming code n stored in the flash memory 40. For example, in the present embodiment, in the case where the trimming code stored in the flash memory 40 is n, the up-down counter 50 operates so that the trimming code output to the trimming resistor 37 changes between n-4 and n. Specifically, in synchronization with rising of the output clock signal 110, the up-down counter 50 changes the trimming code as follows: n→(n-1)→(n-2)→(n-3)→(n-4)→(n-3)→(n-2)→(n-1)→n→(n-1)→ . . . , and so on.

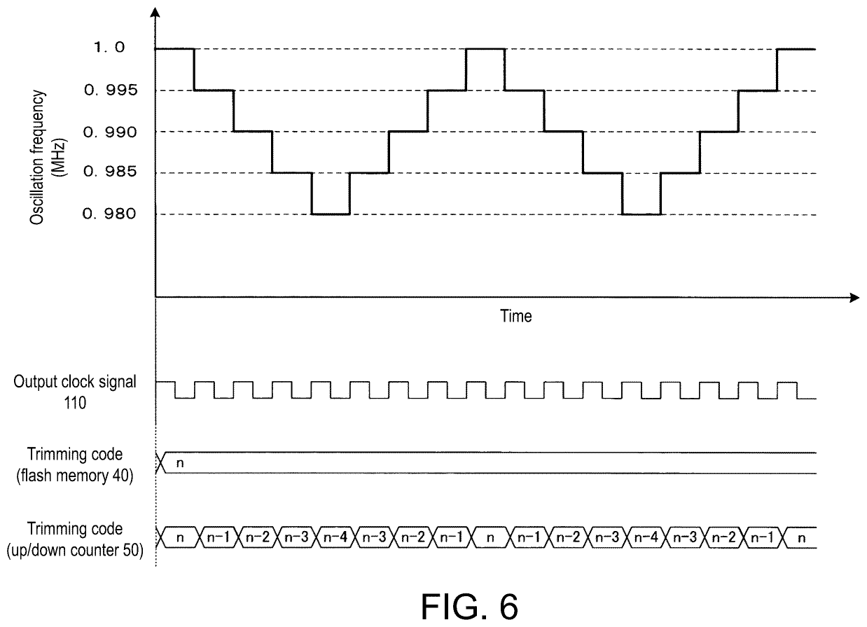

Next, FIG. 6 illustrates an operation waveform in the spread spectrum clock generation circuit of the present embodiment illustrated in FIG. 5.

Referring to FIG. 6, it is known that, while a trimming code read from the flash memory 40 remains constant at n, the trimming code output from the up-down counter 50 changes as follows: n→(n-1)→(n-2)→(n-3)→(n-4) . . . , and so on.

Hence, it is known that, in response to this change in the trimming code, the oscillation frequency of the output clock signal 110 also changes as follows: 1.0 MHz, 0.995 MHz, 0.990 MHz, 0.985 MHz, 0.980 MHz., . . . , and so on.

As described above, in the spread spectrum clock generation circuit of the present embodiment, since the up-down counter 50 that operates according to a logical change of the output clock signal 110 is inserted between the trimming code from the flash memory 40 and the trimming resistor 37, the trimming code output to the trimming resistor 37 changes in synchronization with a clock of the output clock signal 110. Hence, the oscillation frequency of the output clock signal 110 dynamically changes, and the spectrum of the output clock signal 110 is spread. As a result, according to the spread spectrum clock generation circuit of the present embodiment, it is possible to reduce the EMI (radiation noise) of the entire MCU.

In other words, according to the spread spectrum clock generation circuit of the present embodiment, it is possible to realize a spread spectrum technology in which, even if a clock signal is generated using a CR oscillator circuit, a frequency of the generated clock signal can be changed.

In the present embodiment described above, a case has been described of using a trimming method as a method for trimming an oscillation frequency, in which a resistance value is changed using the trimming resistor 37 of the ladder type. However, the disclosure is not limited to such a case. The disclosure can be similarly applied in cases of using a trimming method in which a capacitance value of a capacitive element, rather than the resistance value, is changed according to a trimming code.

Furthermore, the CR oscillator circuit 30 is not limited to a feedback-type oscillator circuit that is composed of an amplifier circuit and a feedback circuit and oscillates and generates a clock signal in response to satisfying an oscillation condition. The disclosure can be similarly applied to a relaxation-type oscillator circuit that generates a clock signal by controlling an on/off timing of a switching element, if the oscillator circuit is an oscillator circuit whose oscillation frequency changes through trimming.

What is claimed is:

1. A spread spectrum clock generation circuit, comprising:
a CR oscillator circuit, generating a clock signal having a frequency based on a time constant determined by a resistance value of a resistive element and a capacitance value of a capacitive element;
a memory element, storing a trimming code for adjusting the resistance value of the resistive element or the capacitance value of the capacitive element so that the frequency of the clock signal generated by the CR oscillator circuit becomes a preset frequency; and
a counter circuit, in synchronization with the clock signal generated by the CR oscillator circuit, increasing or decreasing the trimming code stored in the memory element and outputting the trimming code as the trimming code for adjusting the resistance value of the resistive element or the capacitance value of the capacitive element.

2. The spread spectrum clock generation circuit according to claim 1, wherein
the counter circuit increases or decreases and changes the trimming code stored in the memory element so that the trimming code to be output falls within a preset range from the trimming code stored in the memory element.

3. The spread spectrum clock generation circuit according to claim 1, wherein
the resistive element is a ladder-type trimming resistor whose resistance value changes based on a trimming code input;
the memory element stores the trimming code for adjusting the resistance value of the resistive element so that the frequency of the clock signal generated by the CR oscillator circuit becomes a preset frequency; and
the counter circuit, in synchronization with the clock signal generated by the CR oscillator circuit, increases or decreases the trimming code stored in the memory element and outputs the trimming code as the trimming code for adjusting the resistance value of the resistive element.

4. The spread spectrum clock generation circuit according to claim 2, wherein
the resistive element is a ladder-type trimming resistor whose resistance value changes based on a trimming code input;
the memory element stores the trimming code for adjusting the resistance value of the resistive element so that the frequency of the clock signal generated by the CR oscillator circuit becomes a preset frequency; and
the counter circuit, in synchronization with the clock signal generated by the CR oscillator circuit, increases or decreases the trimming code stored in the memory element and outputs the trimming code as the trimming code for adjusting the resistance value of the resistive element.

5. The spread spectrum clock generation circuit according to claim 1, wherein
the CR oscillator circuit is a feedback-type oscillator circuit that is composed of an amplifier circuit and a feedback circuit and oscillates and generates a clock signal in response to satisfying an oscillation condition, or is a relaxation-type oscillator circuit that generates a clock signal by controlling an on/off timing of a switching element.

6. The spread spectrum clock generation circuit according to claim 2, wherein
the CR oscillator circuit is a feedback-type oscillator circuit that is composed of an amplifier circuit and a feedback circuit and oscillates and generates a clock signal in response to satisfying an oscillation condition, or is a relaxation-type oscillator circuit that generates a clock signal by controlling an on/off timing of a switching element.
